(19) United States
(12) Patent Application Publication
(10) Pub. No.: US 2012/0326191 A1
(43) Pub. Date: Dec. 27, 2012

(54) SEMICONDUCTOR LIGHT-EMITTING DEVICE

(75) Inventor: Szu-Wei Fu, Taichung City (TW)

(73) Assignee: LEXTAR ELECTRONICS CORPORATION, Hsinchu (TW)

(21) Appl. No.: 13/314,357

(22) Filed: Dec. 8, 2011

(30) Foreign Application Priority Data
Jun. 27, 2011 (TW) 100122488

(51) Int. Cl. H01L 33/60

(52) U.S. Cl. 257/98; 257/E33.06

(57) ABSTRACT

A semiconductor light emitting device, including a substrate, an epitaxy layer and an interference thin film is provided. The substrate has a first surface and a second surface opposite to the first surface. The epitaxy layer is disposed on the first surface. The interference thin film is disposed on the second surface. The interference thin film is formed by a plurality of first-material thin films and a plurality of second-material thin films alternately stacked with one another. The difference in refractive index between the first-material and second-material thin films is at least 0.7. The reflection spectrum of the interference thin film has at least one pass band, which allows an incident light of a specific wavelength to pass through. For example, the central wavelength of the incident light ranges 532±10 nm or 1064±10 nm, and the reflectance of the incident light is smaller than 40%.

This application claims the benefit of Taiwan application Serial No. 100122488, filed Jun. 27, 2011, the subject matter of which is incorporated herein by reference.

### BACKGROUND OF THE INVENTION

1. Field of the Invention

The invention relates in general to a semiconductor light emitting device, and more particularly to a semiconductor light emitting device allows a laser light within a specific wavelength range to pass through.

2. Description of the Related Art

Light emitting diode (LED) emits the light through photoelectron conversion. The main constituting material of the light emitting diode is semiconductor, wherein the semiconductor with a higher ratio of holes carrying positive charges is referred as a P-type semiconductor, and the semiconductor with a higher ratio of electrons carrying negative charges is referred as an N-type semiconductor. A PN joint is formed at the junction between the P-type semiconductor and the N-type semiconductor. When voltages are applied to the positive electrode and the negative electrode of an LED, electrons and holes are combined and emitted in the form of the light.

Due to the advantages of long lifespan, low temperature and high energy utilization rate, LED has been widely used in backlight modules, lamps, traffic lights, and brake lights, and has gradually replaced conventional light source.

Referring to FIG. 1, a schematic diagram of a reflection spectrum of a conventional reflective layer is shown. When a distributed Bragg reflector (DBR) is formed on the back of an LED substrate, the light output at the front side of the substrate is increased. However, the wavelength of the incident light ranges 400˜700 nm is a high reflective wave band (the reflectance is above 90%) with respect to the reflective layer. Since the wavelength of the laser light used for singulating the substrate is about 532 nm and such laser light will be reflected back and cannot be used for singulating the substrate in the manufacturing process, problems would therefore occur to the manufacturing process.

### SUMMARY OF THE INVENTION

The invention is directed to a semiconductor light emitting device whose substrate has interference thin film formed thereon for adjusting transmittance and reflectance with respect to various wave bands, so that the laser light within a specific wavelength range can passes through the interference thin film instead of being reflected back.

According to an aspect of the present invention, a semiconductor light emitting device including a substrate, an epitaxy layer and an interference thin film is provided. The substrate has a first surface and a second surface opposite to the first surface. The epitaxy layer is disposed on the first surface. The interference thin film is disposed on the second surface. The interference thin film is formed by a plurality of first-material thin films and a plurality of second-material thin films alternately stacked with one another. The difference in refractive index between the first-material and second-material thin films is at least 0.7. The reflection spectrum of the interference thin film has at least one pass band, which allows an incident light of a specific wavelength to pass through.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a schematic diagram of a reflection spectrum of a conventional reflective layer;

FIG. 2 shows a cross-sectional view of a semiconductor light emitting device according to an embodiment;

FIG. 3 shows a schematic diagram of a reflection spectrum of an interference thin film according to an embodiment;

FIG. 4 shows a cross-sectional view of a semiconductor light emitting device according to an embodiment of the invention; and

FIG. 5 shows a schematic diagram of a reflection spectrum of an interference thin film according to an embodiment.

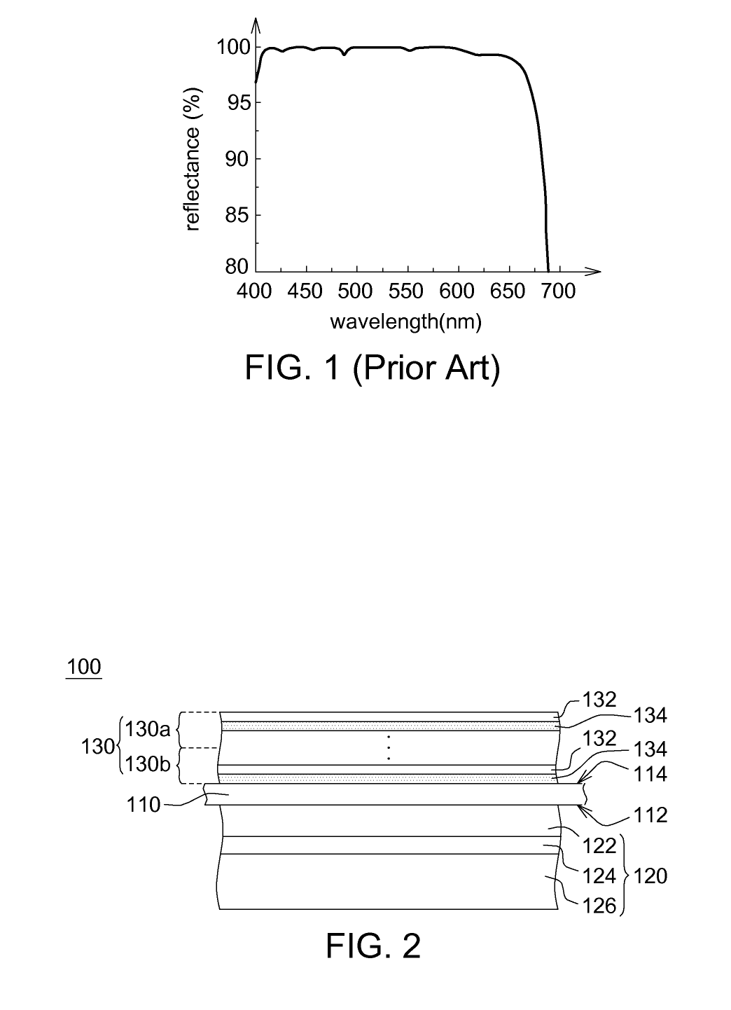

### DETAILED DESCRIPTION OF THE INVENTION

According to the semiconductor light emitting device of the present embodiment, an interference thin film is formed by disposing pairs of compounds on a surface of the substrate, wherein the compounds are composed of material with high refractive index and material with low refractive index alternately stacked with one another. The compounds can be formed by materials such as oxide, nitride, carbide and fluoride. The compounds can sequentially form various film layers with different refractive indexes and optical thicknesses by physical vapor deposition (PVD) process. The optical thickness of each film layer is related to the wavelength of the incident light. When the product of the refractive index of a film layer multiplied by the optical thickness is equal to a quarter of the wavelength of the incident light, the optical path difference between the incident light and the reflected light is a multiple of the wavelength of the incident light (nA, n=1, 2, 3 . . . ), so the generated interference is constructive interference. If the product of the refractive index of a film layer multiplied by the optical thickness is equal to a half of the wavelength of the incident light, the optical path difference between the incident light and the reflected light is equal to an odd-numbered multiple of the half wavelength of the incident light ((2n−1)λ/2, n=1, 2, 3 . . . ), so the generated interference is destructive interference. It can be seen that the interference thin film changes the transfer characteristics of the incident light including the transmission, reflection, absorption, scattering, polarization and phase change of the light through the above-mentioned interference principle and material characteristics. Thus, through suitable design, the present embodiment can modulate the transmittance and reflectance of different wave bands, so that the laser light within a specific wavelength range can pass through the semiconductor light emitting device. For example, the interference thin film allows the incident light whose central wavelength ranges 532±10 nm to pass through and the reflectance is smaller than 40%, but the interference thin film blocks the incident light whose wavelength is other than the specific wavelength to pass through and the reflectance is larger than 90%. When the incident light is a 532 nm or a 1064 nm solid-state laser light possessing high coherence and high energy, the incident light is capable of passing through the interference thin film and can be used for singulating LED substrate such as sapphire substrate, silicon carbide substrate or silicon substrate.

A number of embodiments are disclosed for detailed descriptions of the invention, not for limiting the scope of protection of the invention.

### First Embodiment

Referring to FIG. 2, a cross-sectional view of a semiconductor light emitting device according to an embodiment is shown. The semiconductor light emitting device 100 includes a substrate 110, an epitaxy layer 120 and an interference thin film 130. The substrate 110 has a first surface 112 and a second surface 114 opposite to the first surface 112. The epitaxy layer 120 is disposed on the first surface 112. The epitaxy layer 120 is composed of a first semiconductor layer 122, an active layer 124 and a second semiconductor layer 126 arranged in a top down order. When voltages are applied on the first semiconductor layer 122 and the second semiconductor layer 126, the electrons and holes in the active layer 124 are combined together and emitted in the form of the light.

Besides, the interference thin film 130 is disposed on the second surface 114. The interference thin film 130 is formed by a plurality of first-material thin films 132 and a plurality of second-material thin films 134 alternately stacked with one another. The difference in refractive index between the first-material and second-material thin films is at least 0.7. The total number of layers of the interference thin film 130 at least is larger than 7. The larger the number of layers, the better the effect achieved by the transmittance or the reflectance of the light.

In the present embodiment, the first material is such as titanium dioxide whose refractive index is 2.5, and the second material is such as silicon dioxide whose refractive index is 1.47. The structural formula of the interference thin film 130 located between the substrate 110 and the air can be expressed as:

substrate/(H1L1)^{m}H1(H2L2)^{m}H2/air

Wherein, the relationship between the optical thickness of each film layer and the wavelength of the incident light is as follows:

H1: denotes the optical thickness of the first material thin film 132 (a quarter of the central wavelength 450 nm of the incident light);
L1: denotes the optical thickness of the second material thin film 134 (a quarter of the central wavelength 450 nm of the incident light);
H2: denotes the optical thickness of the first material thin film 132 (a quarter of the central wavelength 644 nm of the incident light);
L2: denotes the optical thickness of the second material thin film 134 (a quarter of the central wavelength 644 nm of the incident light);
m: denotes the number of layers.

In other words, when the product of the refractive index of the first material thin film 132 multiplied by the optical thickness is equal to a quarter of the central wavelength 450 nm, it can be calculated that the optical thickness of the first material thin film 132 is about 45 nm. Likewise, when the product of the refractive index of the second material thin film 134 multiplied by the optical thickness is equal to a quarter of the central wavelength 450 nm, it can be calculated that the optical thickness of the second material thin film 134 is about 76.5 nm. Besides, when the product of the refractive index of the first material thin film 132 multiplied by the optical thickness is equal to a quarter of the central wavelength 644 nm of the incident light, it can be calculated that the optical thickness of the first material thin film 132 is about 64.4 nm. Likewise, when the product of the refractive index of the second material thin film 134 multiplied by the optical thickness is equal to a quarter of the central wavelength 644 nm of the incident light, it can be calculated that the optical thickness of the second material thin film 134 is about 109.5 nm.

Referring to FIG. 2. In the above structural formula of the interference thin film 130, (H1L1)^{m} H1 denotes the first constructive interference thin film 130a, wherein the optical thickness of each film layer is a quarter of the central wavelength 450 nm, and the total number of layers of the first constructive interference thin film 130a at least is larger than 7. Besides, (H2L2)^{m} H2 denotes the second constructive interference thin film 130b, wherein the optical thickness of eachfilm layer is a quarter of the central wavelength 644 nm, and the total number of layers of the second constructive interference thin film 130b at least is larger than 7.

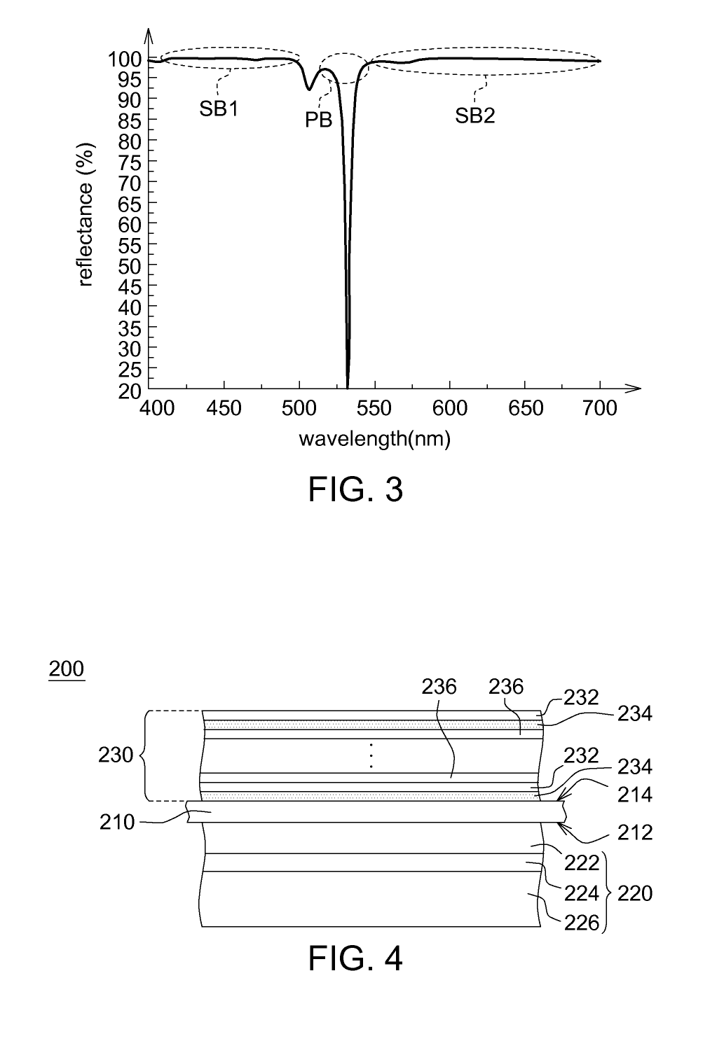

Referring to FIG. 3, a schematic diagram of a reflection spectrum of an interference thin film according to an embodiment is shown. The reflection spectrum of the first constructive interference thin film 130a has a first stop band SB1, which blocks the incident light whose wavelength ranges 400˜500 nm, wherein the reflectance of the first constructive interference thin film 130a is larger than 90%. The reflection spectrum of the second constructive interference thin film 130b has a second stop band SB2, which blocks the incident light whose wavelength ranges 550˜700 nm, wherein the reflectance of the second constructive interference thin film 130b is larger than 90%. A pass band PB whose wave band ranges 500˜550 nm is formed between the first stop band SB1 and the second stop band SB2. Thus, the interference thin film 130 of the present embodiment only allows the incident light whose wavelength ranges 500˜550 nm to pass through. Preferably, the interference thin film 130 only allows the incident light whose central wavelength ranges 532±10 nm to pass through, and the reflectance of the incident light is smaller than 40% or is smaller than 10%. In another embodiment, the interference thin film only allows the incident light whose central wavelength ranges 1064±10 nm to pass through, and the reflectance of the incident light is smaller than 40% or is smaller than 10%.

### Second Embodiment

Referring to FIG. 4, a cross-sectional view of a semiconductor light emitting device according to an embodiment of the invention is shown. The semiconductor light emitting device 200 includes a substrate 210, an epitaxy layer 220 and an interference thin film 230. The substrate 210 has a first surface 212 and a second surface 214 opposite to the first surface 212. The epitaxy layer 220 is disposed on the first surface 212. The epitaxy layer 220 is composed of the first semiconductor layer 222, the active layer 224 and the second semiconductor layer 226 arranged in a top down order. When voltages are applied on the first semiconductor layer 222 and the second semiconductor layer 226, the electrons and holes in the active layer 224 are combined together and emitted in the form of the light.

Besides, the interference thin film 230 is disposed on the second surface 214. The interference thin film 230 is formed by a plurality of first-material thin films 232 and a plurality of second-material thin films 234 alternately stacked with one another, wherein the difference in refractive index between the first-material and second-material thin films is at least 0.7. The total number of layers of the interference thin film 230 at least is larger than 7. The larger the number of layers, the better the effect achieved by the transmittance or the reflectance of the light.

In the present embodiment, the first material is such as titanium dioxide whose refractive index is 2.5, and the second material is such as silicon dioxide whose refractive index is 1.47. The structural formula of the interference thin film 230 located between the substrate 210 and the air can be expressed as:

substrate/(HL)^{m}H2S(HL)^{m}HL(HL)^{m}H2S(HL)^{m}H/air

Wherein, the relationship between the optical thickness of each film layer and the wavelength of the incident light is as follows:

H: denotes the optical thickness of the first material thin film 232 (a quarter of the central wavelength 532 nm of the incident light);
L: denotes the optical thickness of the second material thin film 234 (a quarter of the central wavelength 532 nm of the incident light);
2S: the optical thickness of the space layer 236 being 2 mH or 2 mL denotes the optical thickness of the first material thin film 232 or the second material thin film 234 (a half of the central wavelength 532 nm of the incident light);
m: denotes the number of layers such as 1, 2, 3, and so on.

In other words, when the product of the refractive index of the first material thin film 232 multiplied by the optical thickness is equal to a quarter of the central wavelength 532 nm, it can be calculated that the optical thickness of the first material thin film 232 is about 53.2 nm. Likewise, when the product of the refractive index of the second material thin film 234 multiplied by the optical thickness is equal to a quarter of the central wavelength 532 nm, it can be calculated that the optical thickness of the second material thin film 234 is about 90.5 nm. Besides, when the optical thickness of the space layer 236 is equal to a half of the central wavelength 532 nm of the incident light (let the product of the refractive index of the second material thin film 234 multiplied by the optical thickness be taken for example), it can be calculated that the optical thickness of the space layer is about 181 nm.

In the above structural formula of the interference thin film 230, four constructive interference thin films and three destructive interference thin films are alternately stacked with one another, and the total number of layers at least is larger than 7. (HL)^{m} H denotes a constructive interference thin film, wherein the thickness of the film layer is equal to a quarter of the central wavelength 532 nm or 1064 nm. Besides, 2S denotes a destructive interference thin film, wherein the thickness of the film layer is a half of the central wavelength 532 nm or 1064 nm.

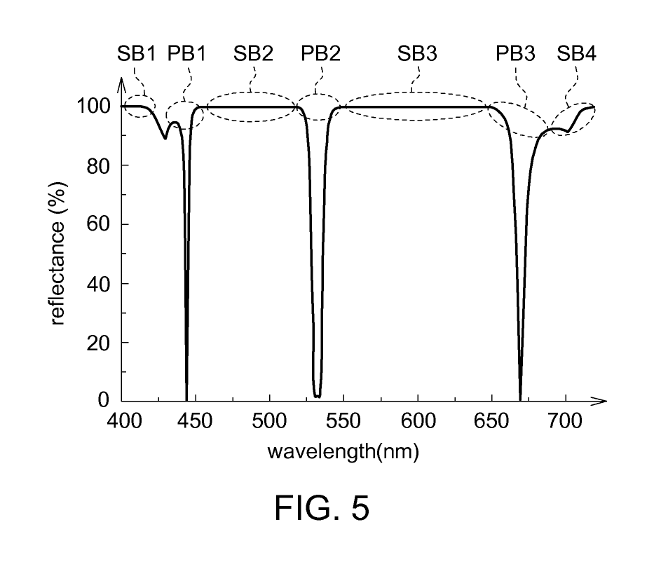

Referring to FIG. 5, a schematic diagram of a reflection spectrum of an interference thin film according to an embodiment is shown. The reflection spectrums of the constructive interference thin films respectively forms one of the four stop bands SB1˜SB4 respectively block the incident light whose wavelength ranges 400˜425 nm, 450˜520 nm, 550˜650 nm and 675˜700 nm to pass through, wherein the reflectance of the interference thin film is larger than 90%. Of the four stop bands SB1˜SB4, three pass bands PB1˜PB3 are formed between every two adjacent stop bands, wherein the wave bands respectively range 425˜450 nm, 520˜550 nm and 650˜675 nm. Besides, the destructive interference thin film allows the incident light whose wavelength ranges 520˜550 nm to pass through. Thus, in the present embodiment, the interference thin film 230 only allows the incident light whose wavelength ranges 425˜450 nm, 520˜550 nm and 650˜675 nm to pass through. Preferably, the interference thin film 230 only allows the incident light whose central wavelength ranges 435 nm±10 nm, 532±10 nm and 662±10 nm to pass through, and the reflectance of the incident light is smaller than 40%.

According to the semiconductor light emitting device of the present embodiment, an interference thin film is formed by disposing pairs of compounds on a surface of the substrate, wherein the compounds are composed of material with high refractive index and material with low refractive index alternately stacking with one another. The interference thin film changes the transfer characteristics of the incident light through the abovementioned interference principle and material characteristics. Thus, through suitable design, the present embodiment can modulate the transmittance and reflectance of different wave bands, so that the laser light within a specific wavelength range can pass through the semiconductor light emitting device.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor light emitting device, comprising:
a substrate having a first surface and a second surface opposite to the first surface;
an epitaxy layer disposed on the first surface; and
an interference thin film disposed on the second surface, wherein the interference thin film is formed by a plurality of first-material thin films and a plurality of second-material thin films alternately stacked with one another, the difference in refractive index between the first-material and second-material thin films is at least 0.7, and the reflection spectrum of the interference thin film has at least one pass band, which allows an incident light of a specific wavelength to pass through the interference thin film.

2. The semiconductor light emitting device according to claim 1, wherein the specific wavelength ranges 532±10 nm or 1064±10 nm.

3. The semiconductor light emitting device according to claim 2, wherein the reflectance of the incident light of a specific wavelength is smaller than 40%.

4. The semiconductor light emitting device according to claim 2, wherein the interference thin film blocks the incident light whose wavelength is other than the specific wavelength and the reflectance is larger than 90%.

5. The semiconductor light emitting device according to claim 1, wherein the total number of layers of the interference thin film at least is larger than 7.

6. The semiconductor light emitting device according to claim 1, wherein the first material is titanium dioxide, and the second material is silicon dioxide.

7. The semiconductor light emitting device according to claim 1, wherein the interference thin film comprises:
a first constructive interference thin film formed by a plurality of first-material thin films and a plurality of second-material thin films alternately stacked with one another to form a first stop band which blocks the incident light whose wavelength ranges 400˜500 nm, and the thickness of the first-material and second-material thin films is a quarter of the central wavelength; and
a second constructive interference thin film located on the first constructive interference thin film formed by a plurality of first-material thin films and a plurality of second-material thin films alternately stacked with one another to form a second stop band which blocks the incident light whose wavelength ranges 550˜700 nm, and the thicknesses of the first-material and second-material thin films are a quarter of the central wavelength.

8. The semiconductor light emitting device according to claim 7, wherein the total number of layers of the first constructive interference thin film at least is larger than 7, and the total number of layers of the second constructive interference thin film at least is larger than 7.

9. The semiconductor light emitting device according to claim 1, wherein the interference thin film comprises:
a plurality of constructive interference thin film formed by a plurality of first-material thin films and a plurality of second-material thin films alternately stacked with one another to form several stop bands, which respectively block the incident light whose wavelengths range 400˜425 nm, 450˜520 nm, 550˜650 nm and 675˜700 nm, wherein the thicknesses of the first-material and second-material thin films are a quarter of the central wavelength; and
a plurality of destructive interference thin films interlaced with the constructive interference thin films, wherein the thickness of the destructive interference thin films is a half of the central wavelength, and the destructive interference thin films allow the incident light whose wavelength ranges 520˜550 nm to pass through.
